(19) United States
(12) Patent Application Publication
(10) Pub. No.: US 2023/0027916 A1
(43) Pub. Date: Jan. 26, 2023

(54) DEVICE AND SYSTEM FOR DETERMINING PROPERTY OF OBJECT

(71) Applicant: Chia-Hung CHEN, New Taipei (TW)

(72) Inventors: Chia-Hung CHEN, New Taipei City (TW); Chia-Chi SU, Taichung (TW)

(21) Appl. No.: 17/785,307

(22) PCT Filed: Dec. 28, 2020
(86) PCT No.: PCT/CN2020/140185

§ 371 Date: Jun. 14, 2022

Related U.S. Application Data
(60) Provisional application No. 62/953,929, filed on Dec. 27, 2019.

(51) Int. Cl. H03B 5/06; G01K 3/00

(52) U.S. Cl. CPC H03B 5/06; G01K 3/005

(57) ABSTRACT

A sensing device and a determining system for determining the location, the movement or even other properties of one or more objects. A sensing device is attached to one object, and contains at least a trigger module and a sound module. The trigger module is configured to generate a sensing signal, and the sound module is configured to generate and transmit a wide-frequency sound signal correspondingly. The determining system contains at least one such sensing device and an analyzing device configured to receive and analyze the wide-frequency sound signal. Therefore, one or more properties of the object(s) may be monitored. In general, the trigger module is configured to couple electrically one or more crystal oscillators with the sound module, so that the oscillation signal generated thereby may be controllably converted into the wide-frequency sound signal.

### FIELD OF THE INVENTION

The present invention relates to device and system for determining property of object, and more particularly to device and system thereof utilizing at least the amplitude and the frequency of the wide-frequency sound signal transmitted by the device.

### BACKGROUND OF THE INVENTION

In recent years, the requirements for the detection of position, movement, even other properties of one or more object are continuously increased. For example, the drastically rise of many applications of the internet of things (IoT). For example, the increased demand for the automated warehousing and the automated logistics, as well as the intelligent fitness equipment.

Generally speaking, till now, the sensor placed on the object to detect one or more properties of the object uses one or more of the following technologies: gyroscopes, motion sensors, multi-axis sensors, Hall elements, piezoelectrics, magnetometers, imaging optics, infrared elements, other fixed electronic components, and proximity, etc. Also, such object popularly uses the Bluetooth, Wi-Fi, other wireless chips or even cable lines to transmit the signal of the detected one or more properties.

However, all these currently available sensors are still limited unavoidably by the following disadvantages: (1) the finite channels of the wireless connections, such as Bluetooth and Wi-Fi, which usually limits the connection between a sensor and its corresponding analyzing device while the analyzing device may have to connect with other sensor(s), even other device(s). (2) the power consumption and the hardware cost required to build up the sensor. (3) the sensitivity, the reliability, the complexity of corresponding algorithms, the limited signal transmission distance and the low spatial flexibility of capable lines.

Significantly, it is still necessary to develop new technology for more appropriately detect one or more properties of one or more objects distributed among a space.

### SUMMARY OF THE INVENTION

The provided invention presents a sensing device and a determining system for determining the location, the movement, or even other properties of one or more objects distributed among a space. In the determining system, some sensing devices are attached to some separated objects respectively, such that the detected properties of one or more objects are transmitted by the sensors as some wide-frequency sound signals (such as audio signal or an ultrasonic signal) to be received and analyzed by an analyzing device (such as smartphone, pad and laptop installed with relative Apps). Each sensing device contains at least a trigger module and a sound module, wherein the former is configured to detect one or more properties of an object attached thereby and the latter is configured to transmit a wide-frequency sound signal according to the detecting result of the former. Thus, when a property of an object has a specific value, the trigger module attached thereon may detect it and then send a message to the sound module thereon so that a corresponding wide-frequency sound signal is transmitted to a corresponding analyzing device where the property of the object may be determined by analyzing the received signal transmitted from the sound module.

In general, by using the crystal oscillator, many embodiments of this invention provides simply and effectively the required wide-frequency sound signals. Due to a crystal oscillator may provide an oscillation signal, it is benefit to assembly the trigger module, the crystal oscillator and the sound module as a circuit. In this way, when a property of an object is detected to have a first value, the trigger module may be triggered to connect electrically the crystal oscillator and the sound module so that the oscillation signal is converted into the wide-frequency sound signal. In contrast, when the property of an object is not detected or is detected to have another value, the trigger module may be not triggered so that the crystal oscillator and the sound module is not connected electrically and then no wide-frequency sound signal is not converted from the oscillation signal.

To use the crystal oscillator have at least the following advantages: a) many available commercial products may be flexibly chosen. b) low cost, low power consumption and easy to operate. c) the generated oscillation signal may be converted simply into the wide-frequency sound signal. Moreover, to use the wide-frequency sound signal have at least the following advantages: a) will not compete with currently popularly used technologies such as Bluetooth, Wi-Fi and/or other wireless communication. b) the interference may be reduced simply by adjusting the frequencies of different wide-frequency sound signals transmitted by different sensing device. c) low cost, low power consumption and easy to operate.

Note that the wide-frequency sound signal just transmitted away the sound module is almost different than the wide-frequency sound signal just received by the analyzing device, due to the Doppler effect that the signal frequency depends on the moving velocity between each other and the phenomena that the signal amplitude is inversely proportional to the distance between each other. Reasonably, the variation of both the frequency and the amplitude of the wide-frequency sound signal may be used to determine both the relative motion and the relative distance between the analyzing device and the sensing device.

Besides, how to active the trigger module is not limited, i.e., different embodiments may use different hardware to detect the value of a property and to co-work with the sound module. For example, the thermistor may be used to detect the temperature of an object so that the sound module may transmit an object-temperature-relative signal according to the detected object temperature. For example, the magnet may be used to detect whether an object is locked by a magnetic button so that such message is converted by the voice module to notify the analyzing device about the status of the object. For example, on some embodiments, the trigger module may be triggered separately when different values of a property are measured on different times and then allow different oscillation signals provided by different crystal oscillators to be converted by the sound module respectively. For example, on some embodiments, the trigged module is configured to be triggered continuously or not triggered continuously so that the wide-frequency sound signal just transmitted way the sound module is fixed and then only the variation of the amplitude and/or the frequency of the received wide-frequency sound signal is used to analyze the position and/or movement of the object.

### BRIEF DESCRIPTION OF THE DRAWINGS

Other advantages, objectives and features of the present invention will become apparent from the following description referring to the attached drawings.

FIG. 1A schematically illustrates the relation between the determining system and the sensing device, and FIG. 1B schematically illustrates how the determining system with some sensing devices are used to detect some objects similar or non-similar with each other.

FIG. 2A to FIG. 2B schematically illustrates two essential structures of the sensing device respectively.

FIG. 3A to FIG. 3I schematically illustrates some variation of the sensing module respectively.

FIG. 4 schematically illustrates some experimental results related to one variation of the sensing module.

FIG. 5 schematically illustrates some experimental results related to one variation of the determining system.

### DETAILED DESCRIPTION OF THE INVENTION

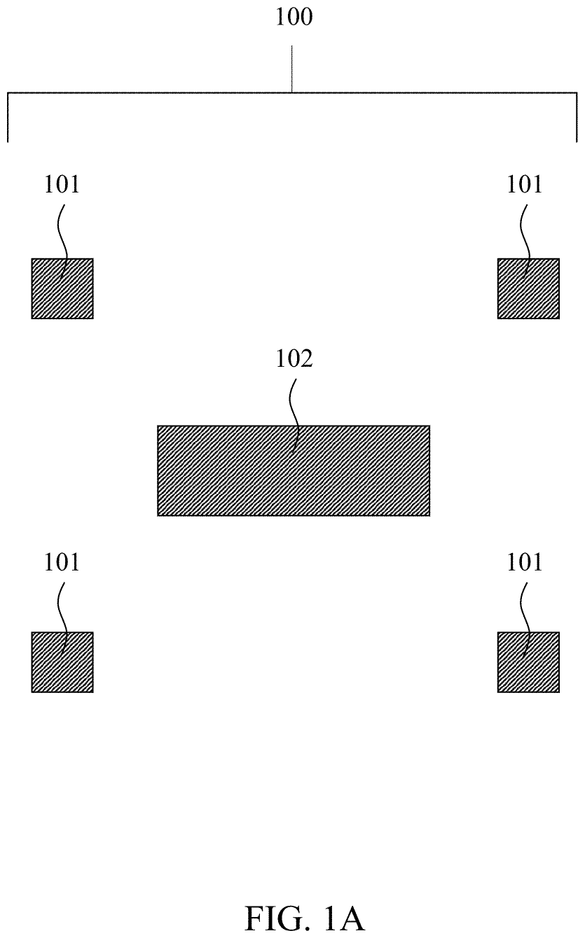

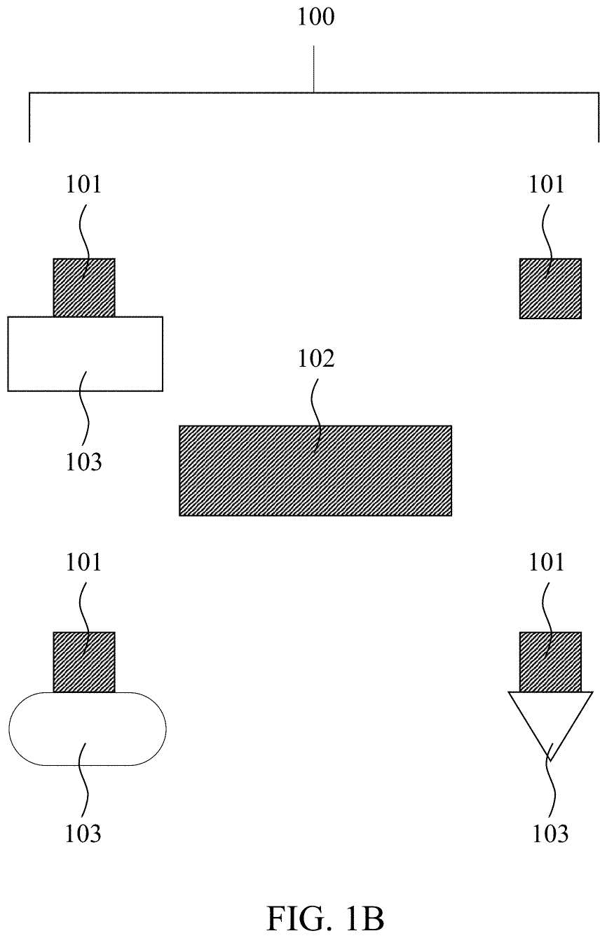

The invention provides a sensing device and a determining system capable of detecting one or more properties of one or more objects distributed among a space. For example, to detect the position, the movement direction, the movement velocity or even the temperature of one or more objects distributed among a finite space, such as the electrochemical sensor in VOCs (Volatile Organic Compounds), humidity sensors, gas sensors, and electronic light sensor, etc. In the determining system, one or more of the sensing devices are attached to one or more objects respectively so as to generate and transmit one or more wide-frequency sound signals corresponds to one or more properties of these objects respectively, and an analyzing device (such as smartphone, pad, laptop or other devices capable of running Apps) is used to receive and analyze these wide-frequency sound signals so as to understand one or more properties of each of these objects. FIG. 1A schematically illustrates the relation between the determining system 100 and the sensing device 101, wherein the analyzing device 102 is also illustrated. Also, FIG. 1B schematically illustrates how the determining system 100 with some sensing devices 101 are used to detect some objects 103 similar or non-similar with each other, wherein a sensing device 101 may be not used to detect one or more properties of an object but to detect one or more properties of a location in the space (such as temperature), as shown in the right-upper portion of FIG. 1B.

One main feature of this invention may be emphasized by comparing with these currently available sensors mentioned above. Significantly, the usage of the wide-frequency sound signal is a main feature of this invention, no matter the wide-frequency sound signal is an audio signal can be heard by human or an ultrasonic signal can not be heard by human, also no matter what the frequency of the wide-frequency sound signal has. Although, just for example, 18-22 KHz or even 24-48 KHz may be suitable enough for some commercial applications, such as the intelligent fitness equipment. One major advantage of the usage of the wide-frequency sound signal is not limited by the limited number of channels provided by Bluetooth, Wi-Fi or other currently available wireless communication, especially such usage need not to compete with other commercial products for the finite wireless communication channels of the analyzing device when it is a smartphone, a laptop and/or a pad that usually using Bluetooth and/or Wi-Fi to communicate with other devices though wireless channels. Note that the required frequency bandwidth is not larger for each sensing device because it is only used to deliver the messages related to the position, the movement and/or the temperature or other properties of an object attached by but not to deliver the contents of a song, a picture or even a movie or other larger file. Also, note that an analyzing device may communicate with a number of sensing device by simply using a receiver capable of receiving different sound signals of multiple frequencies in a large frequency range. In this way, an analyzing device may communicate with more sensing devices than what it may communicate with by using Wi-Fi, Bluetooth or any other currently available wireless communication, also it may avoid any interference with the communication between the analyzing device and any other device through Wi-Fi, Bluetooth or any other currently available wireless communication.

One more advantage of the usage of the wide-frequency sound signal is that there are many currently available commercial products/technologies. Hence, advantage of the usage of the wide-frequency sound signal may be archived effectively without obvious technology and/or cost troubles. In addition, different sensing devices 101 are configured to transmit different wide-frequency sound signals with different frequencies, so that the analyzing device 102 may distinguish effectively different signals from different sensing devices 101. However, optionally, two or more sensing devices 101 may transmit individual wide-frequency sound signals with same frequency, if these sensing devices are attached to different objects separated far away, even if the confusion and/or the interference between these signals are acceptable when these sensing devices are not far away each other.

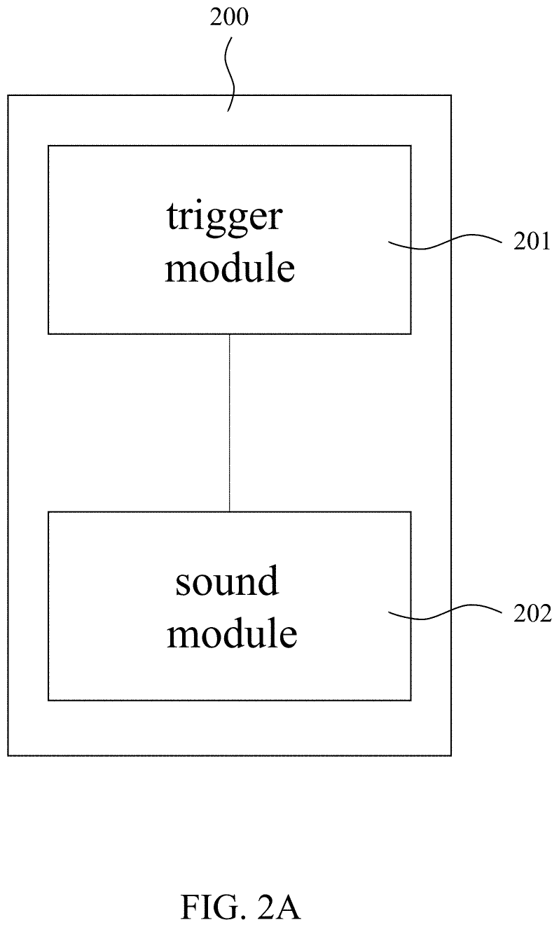

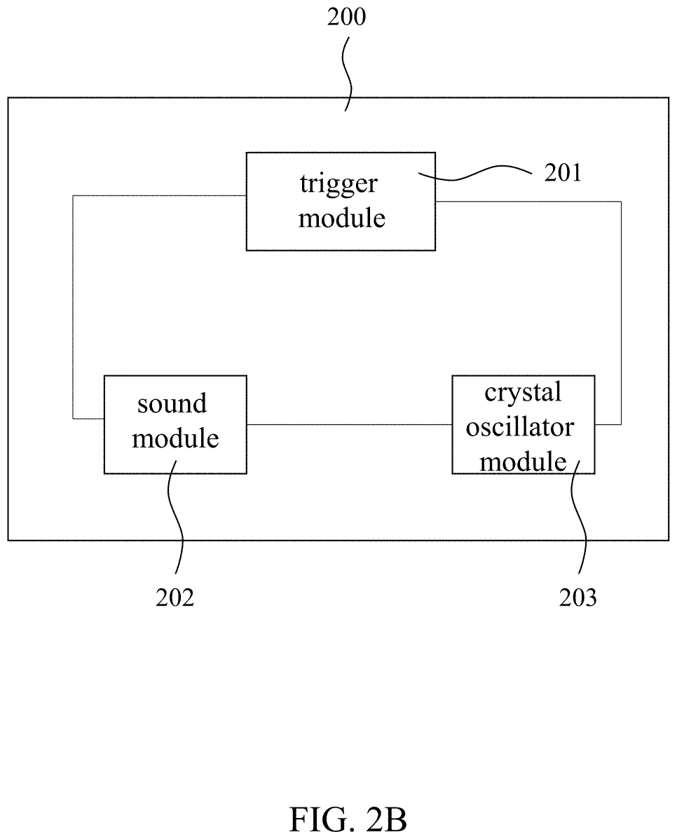

Furthermore, the structure of the sensing device 200 contains essentially a trigger module 201 and a sound module 202, as shown in FIG. 2A, and usually contains one more crystal oscillator module 203, as shown in FIG. 2B. The trigger module 201 is configured to generate a sensing signal corresponding to one or more properties of an object attached by the sensing device 200 (or one or more properties of a position where the sensing device 200 is placed in some special situations), and the sound module 202 is configured to generate and transmit a wide-frequency sound signal according to the sensing signal (or viewed as the trigger situation of the trigger module 201). Simply to say, whenever the trigger module 201 detects that the value of a certain property of the attached object exceeds a threshold value (just for example, whenever the inclination angle of the horizontal axis of the attached object is larger than a certain angle), the sensing module 201 sets the value of the sensing signal to be 1 or a first certain value so as to inform the sound module 202 for generating and transmitting a wide-frequency sound signal correspondingly. Otherwise, whenever the trigger module 201 sets the value of the sensing signal to be zero or a second certain value so as to inform the sound module 202 for not generating and transmitting any wide-frequency sound signal or even for generating and transmitting another wide-frequency sound signal corresponding to the second certain value. In short, depending on what value of one or more properties of the attached object is detected, the sensing module 200 may not generate and transmit any wide-frequency sound signal, also may generate and transmit different wide-frequency sound signals with different vales.

Particularly to emphasize, if only consider using the wide-frequency sound signal to replace Wi-Fi, Bluetooth or other wireless communication, how the sound module 202 generates the wide-frequency sound signal according to the trigging situation of the trigger module 201 is not limited in this invention. In other words, any well-know, on-developing and/or to be appeared technology may be used by the invention to generate and transmit the required wide-frequency sound signal. However, a simple and low cost approach is using the crystal oscillator, because any crystal oscillator may provide an oscillation signal, especially a high precision oscillation signal. In such approach, the trigger module 201, the crystal oscillator module 203 and the sound module 202 forms a circuit. When the trigger module 201 is triggered. both the oscillation signal generated by the crystal oscillator module 203 and the sensing signal are transmitted into the sound module 202 and then used to generate the wide-frequency sound signal. In contrast, when the trigger module 201 is not triggered, both the oscillation signal generated by the crystal oscillator module 203 and the sensing signal are not transmitted into the sound module 202 and then no wide-frequency sound signal is generated correspondingly. Further, in this way, each crystal oscillator generates an individual oscillation signal and the oscillation signal generated by the crystal oscillator module 203 is dependent on at least which portion of the one or more crystal oscillators are connected electrically with the trigger module 201 and the sound module 202. Therefore, by using the crystal oscillator module 203 having one or more crystal oscillators and controllably adjusting the operation of the crystal oscillator module 203, the oscillation signal outputted by the crystal oscillator module 203 may be used to generate the wide-frequency sound signal. Just for example, the outputted oscillation signal may be adjusted to have a frequency about 20 KHz and then the sound module 202 may have a horn diaphragm capable of converting it into an ultrasonic wave signal having a frequency about 20 KHz. Just for example, the outputted oscillation signal may be adjusted to have a frequency about 5 KHz and the sensing signal mat have a value 3, hence, the sound module 202 may have a mixing circuit and a horn diaphragm so that both the oscillation signal and the sensing signal are mixed and then converted into an ultrasonic wave signal having a frequency about 15 KHz. Of course, in some situations, the frequency of the wide-frequency sound signal is fixed and not dependent on the operation of the trigger. For example, the trigger module 201 of a special object may be always triggered and then the ultra-frequency sound signal is transmitted continuously, i.e., the analyzing device of the determining system may monitor the special object continuously.

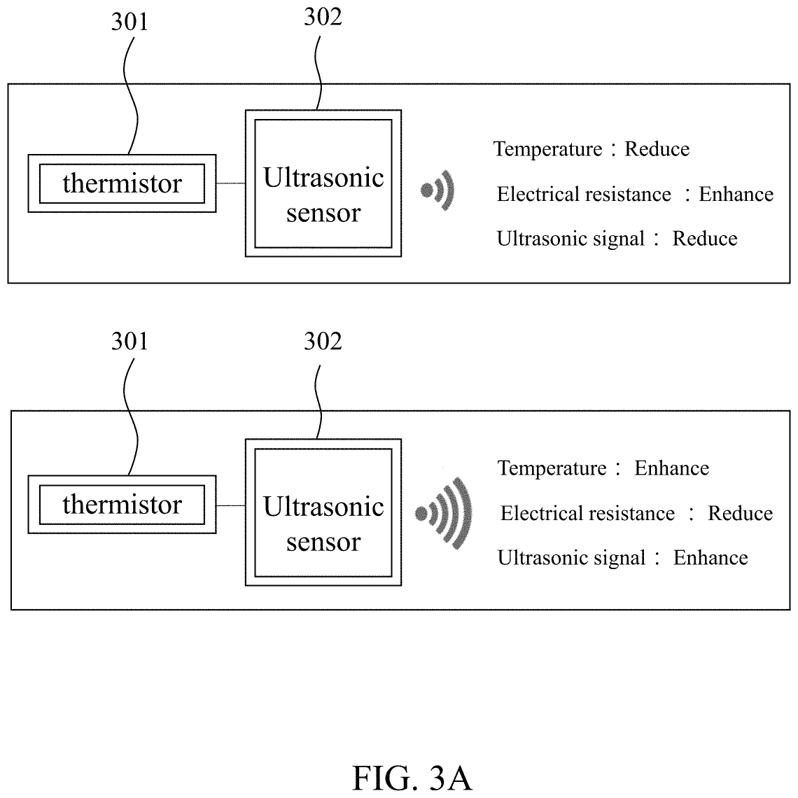

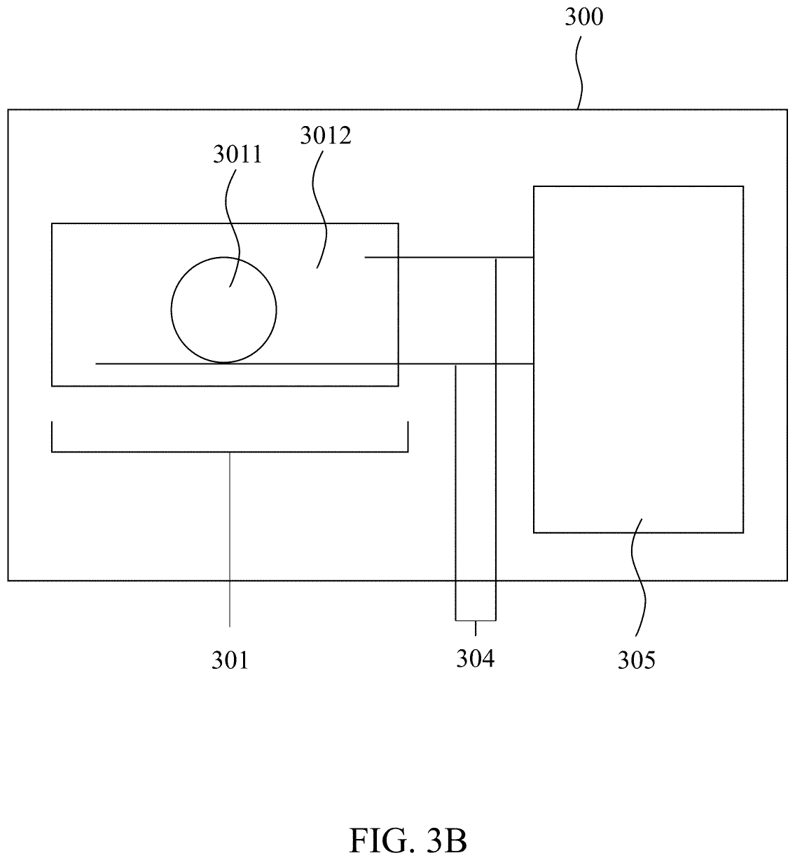

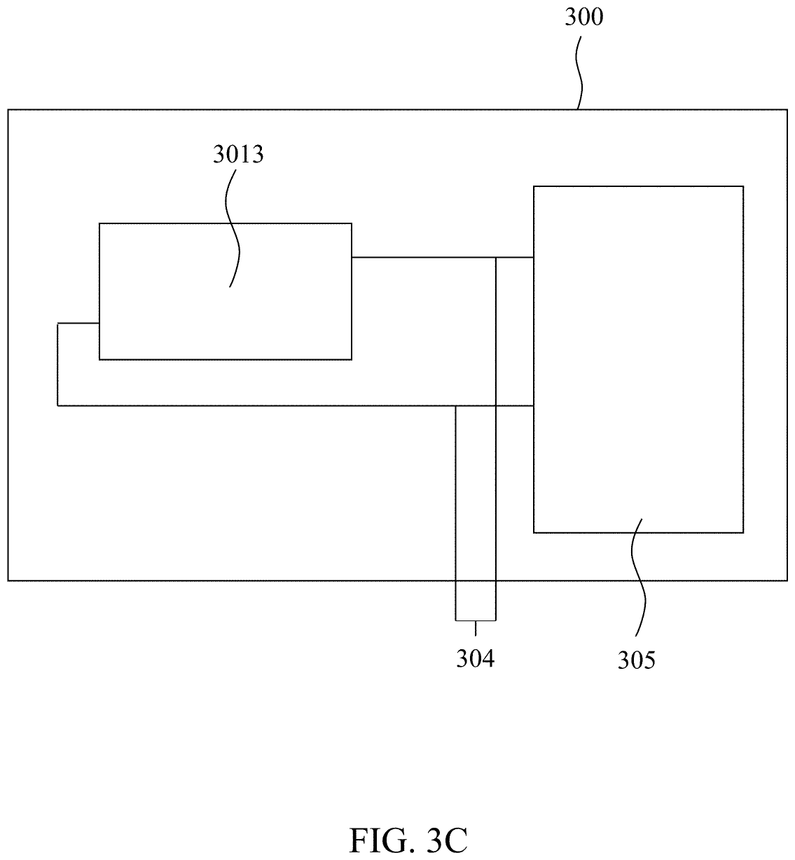

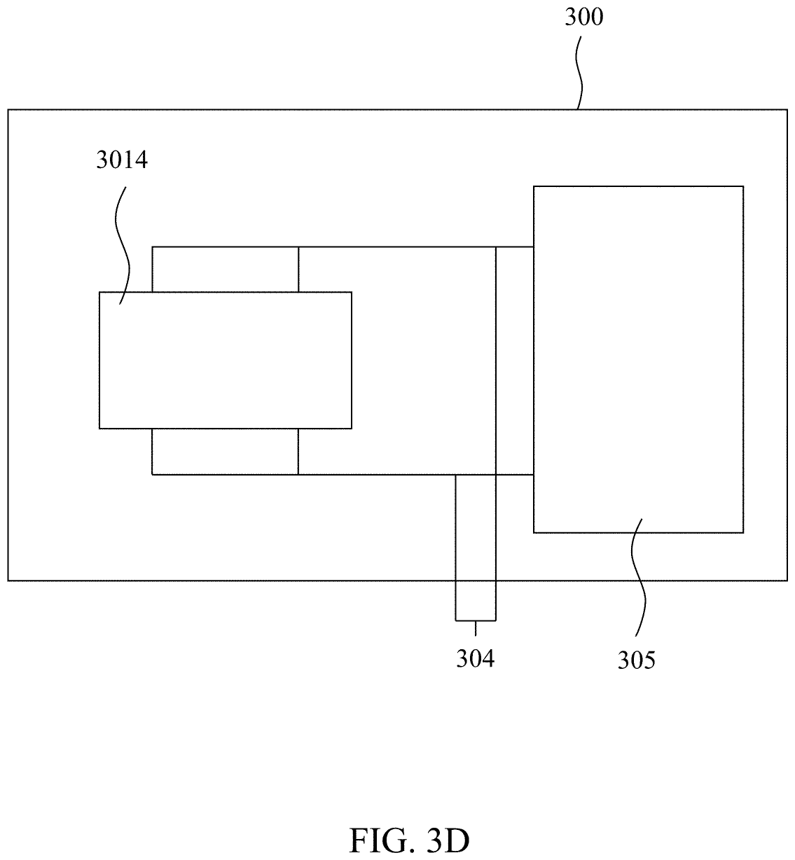

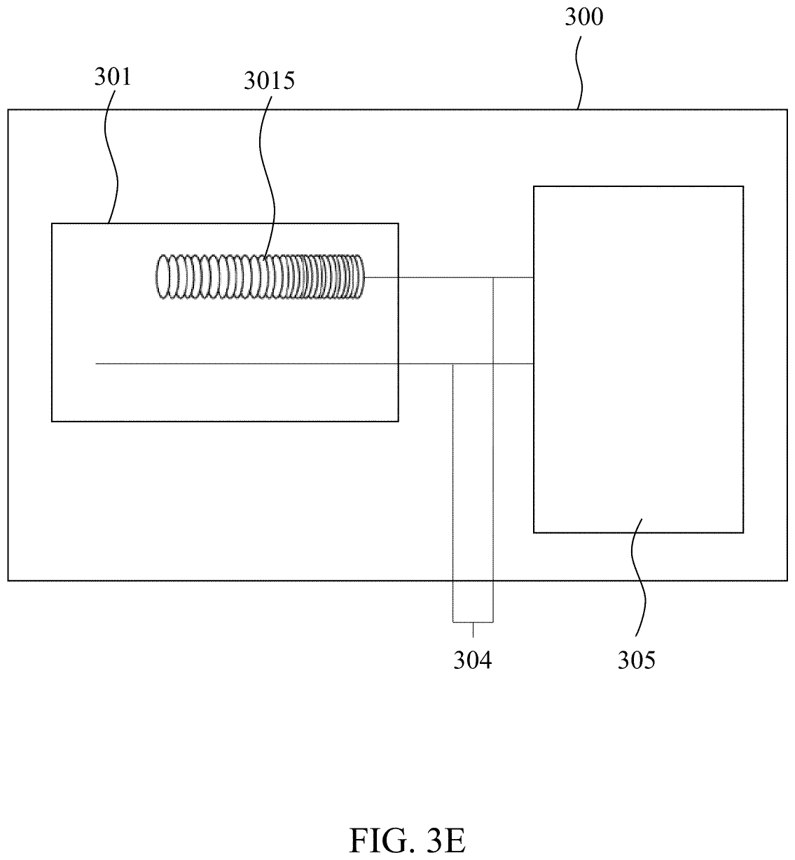

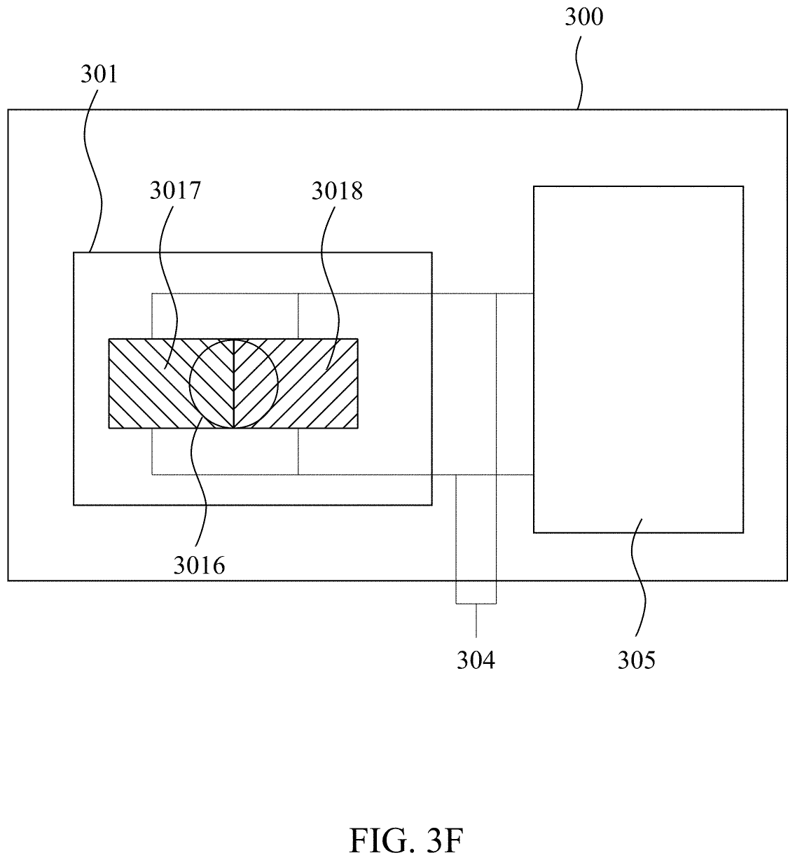

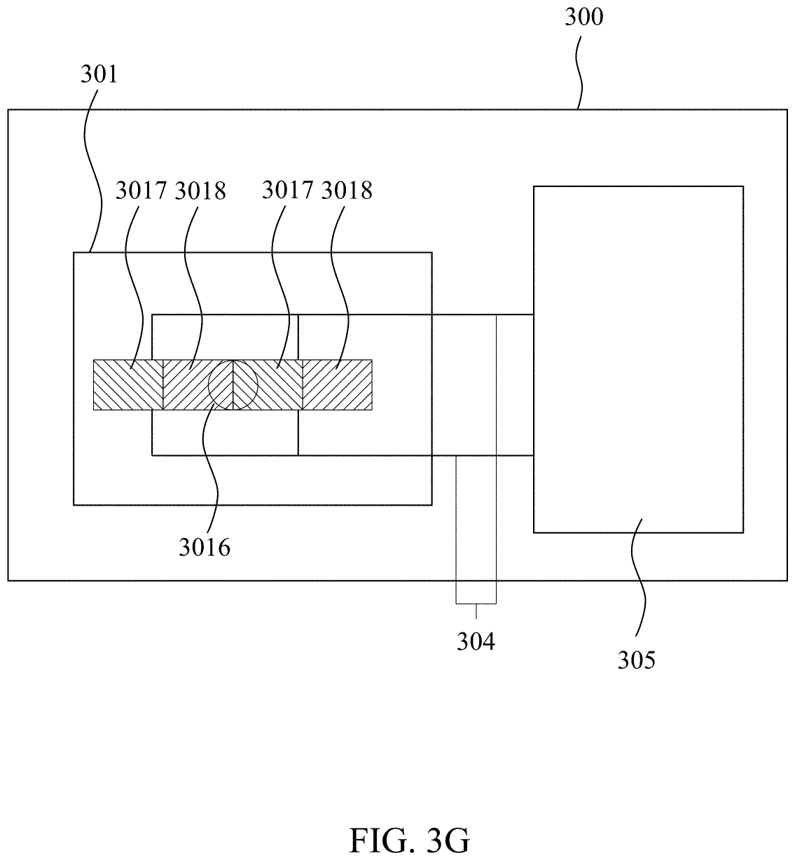

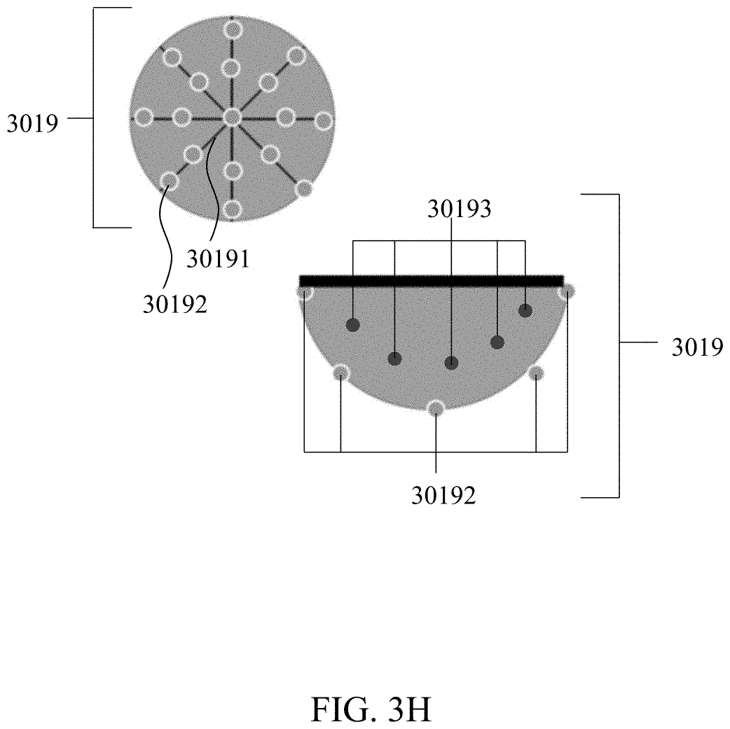

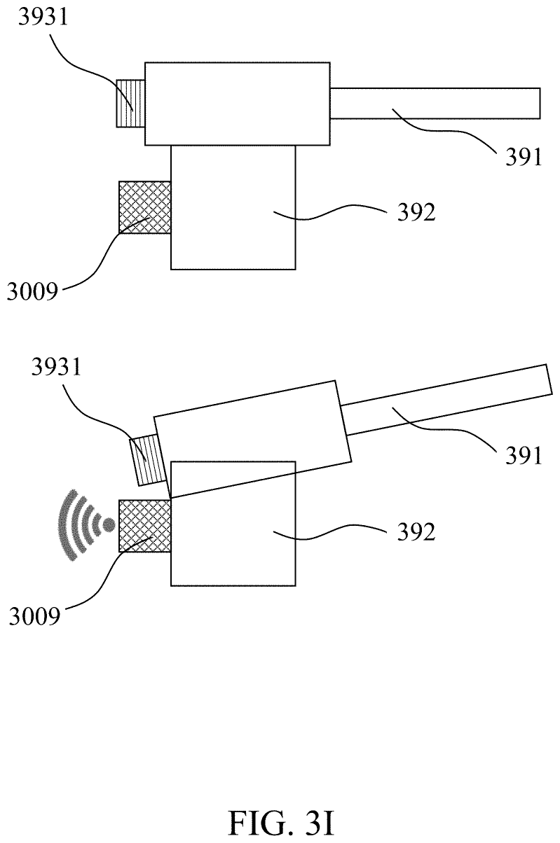

Furthermore, the details of the trigger module 201 also is mot limited. Indeed, it depends on what property of the attached object to be detect, even same to-be-detected property may be detected by different kinds of the trigger module 201. Just for example, FIG. 3A to FIG. 3H schematically illustrates some useful kinds of the trigger module 201 respectively.

FIG. 3A is related to the situation that the trigger module 301 contains a thermistor so that the sensing signal is related to a temperature detected by the thermistor, wherein the sound module 302 contains an ultrasonic sensor. Reasonably, the amplitude of the ultrasonic signal (i.e., the wide-frequency sound signals) is reduced if the electrical resistance is enhanced by the reduce of the detected temperature (such as the temperature of an objected attached thereby), and vice versa. Herein, it may be viewed as the intrinsic oscillation signal of the sound module 302 is fixed so that the outputted ultrasonic signal behaves as a function of both the intrinsic oscillation signal and then sensing signal being changed proportional to the change of the temperature detected by the thermistor. Cleary, in such situation, the trigger module 301 may be triggered continuously so that the sensing signal is outputted and changed continuously.

FIG. 3B is related to the situation that the trigger module 301 contains a conductor ball 3011, such as a metal ball, located inside a pipe 3012 so that the sensing signal is related to an inclination detected by the conductor ball 3011 located inside the pipe 3012. Clearly, because the conductive lines 304 connected electrically to other portions (includes but not limited to the sound module) 305 of the sensing device 300, are connected electrically to different portions of the pipe 3012, the trigger module 301 and the other portions 305 forms a closed circuit when the conductor ball 3011 is positioned in the right terminal of the pipe 3012 but forms an open circuit when the conductor ball 3011 is positioned in other portions of the pipe 3012. Thus, the trigger module 301 is triggered only when the conductor ball 3011 is not rolled off the right terminal of the pipe 3012, which means the trigger module may be used to detect the inclination of the object attached by the sensing device 300 along the axial direction of the pipe 3012.

FIG. 3C is related to the situation that the trigger module 301 contains a mercury switch 3013 so that the sensing signal is related to an inclination detected by the mercury switch. The mercury switch 3013 is a well-known commercial product capable of measuring the inclination and/or the deformation because a droplet of mercury is storage inside a container while some portions of the container are conductor. Hence, the details of the mercury switch 3013 is omitted herein. Two conductor portions of the container of the mercury switch 3013 are connected electrically to other portions (includes but not limited to the sound module) 305 of the sensing device 300 through the conductive lines 304. Hence, the inclination of the mercury switch 303 may decide whether a closed circuit or an open circuit is formed, and then such trigger module 301 may be used to detect the inclination of the object attached by the sensing device along the direction connecting the two conductor portions of the container of the mercury switch 3013.

FIG. 3D is related to the situation that the trigger module 301 contains a Hall effect switch 3014 so that the sensing signal is related to a magnetic field detected by the Hall effect switch 3014. The hall effect switch 3014 is a well-known commercial product capable of detecting a magnetic field and then be switched on and/or off depending on the strength of the detected magnetic field. Hence, the details of the Hall effect switch 3014 is omitted herein. By using the conductive lines 304 to connect electrically the switch on position and the switch off position with other portions (includes but not limited to the sound module) 305 of the sensing device 300, the magnetic field detected by the Hall effect switch 3014 may decide whether a closed circuit or an open circuit is formed, and then such trigger module 301 may be used to detect the magnetic field around the object attached by the sensing device 300 or the magnetic field around the position where the sensing device is placed.

FIG. 3E is related to the situation that the trigger module 301 contains a spring switch 3015 so that the sensing signal is related to a motion detected by the spring switch 3015. One end of the spring switch 3015 is fixed and connected to a conductive line 304 connecting electrically to other portions (includes but not limited to the sound module) 305 of the sensing device 300, and another end of the spring switch 3015 is free and closed to another conductive line 304 connecting electrically to other portions 305 of the sensing device 300. Hence, the spring switch 3015 will touch the both conductive lines 304 simultaneously and form a closed circuit when the spring switch 3015 swings along some certain direction for more than some threshold amplitude respectively, but the spring switch 3015 will not touch both conductive lines 304 simultaneously and then an open circuit is formed if the swing along these certain directions has no enough amplitude or if the spring switch 3015 swings along other directions. That is to say, whether the object attached by the sensing device 300 swings along the certain directions with amplitudes larger than these threshold amplitudes may be detected by using the spring switch 3015.

FIG. 3F is related to the situation that the trigger module 301 contains a roll ball 3016 located inside a combination of a conductive tube 3017 and an insulated tube 3018 so that the sensing signal is decided by whether the roll ball enters the conductive tube 3017 or the insulated tube 3018. Reasonably, this kind is a variation of the kind shown in FIG. 3A and may be used to detect the inclination of the object attached by the sensing device 300 along the axis direction of these tubes 3017/3018. Herein, the two conductive lines 304 are connected to two opposite points of the conductive tube 3017 and also to the other portions (includes but not limited to the sound module) 305 of the sensing device 300, and then whether a closed circuit or an open circuit is formed is decided by how the roll ball 3016 is moved.

FIG. 3G is related to the situation that the trigger module 301 contains a roll ball 3016 located inside a combination of one or more conductive tubes 3017 and one or more insulated tubes 3018 so that the sensing signal is decided by which conductive tube 3017 is entered by the roll ball 3016. Reasonably, this kind is a further variation of the kind shown in FIG. 3F and may be used to detect more precisely and flexibly the inclination of the object attached by the sensing device 300 along the axis direction of these tubes 3017/3018. Herein, the two conductive lines 304 are connected to two opposite points for each of these conductive tube 3017 and also to the other portions (includes but not limited to the sound module) 305 of the sensing device 300, and then whether a closed circuit or an open circuit is formed is decided by how the roll ball 3016 is moved.

FIG. 3H is related to the situation that the trigger module 301 contains a spherical structure 3019 wherein some conductive lines 30191 and some holes 30192 are embedded with the inner of the spherical surface and wherein some conductive balls 30193 are located on the inner of spherical structure. Moreover, each conductive line 30191 has one or more holes 30192 and each hole 30192 may be filled fully by at least one conductive ball 30193. Reasonably, this kind is a further variation of the kind shown in FIG. 3G and may be used to detect more precisely and flexibly the motion of the object attached by the sensing device 300 along many directions being intersected with the inner surface of the spherical structure 3019. Note that a conductive line 30191 having some holes 30192 may behave as an interleaved combination of some conductive tubes and insulated tube, also note that the fully filling of these holes 30192 by some conductive balls 30193 may be viewed as connecting electrically with both conductive lines to form a closed circuit. Besides, different conductive lines positioned on different portions of the inner the spherical surface along different directions may be used to detect the distribution of these conductive balls 30193 on different positions along different directions, which may detect more messages than these kinds shown above that only detect the variation along essentially one and only one axis. Therefore, by using the spherical structure, the sensing signal is related to the multiple dimensions motion detection with speed and gravity effects, i.e., the multiple dimensions' motion of the objected by the sensing module 300 may be detected well. Herein, to simplify figures, only the spherical structures 3019 are illustrated.

FIG. 31 is related to the situation that the sensing signal is related to the relative movement between two objects (or viewed as two parts of a larger object). As shown in FIG. 31, two objects 391 and 392 are closed to each other, and both object 391 and object 392 are attached by a magnet 3931 and a sensing device 3009 capable of detecting the neighboring magnetic field respectively. Reasonable, the strength of the magnetic field detected by the sensing device 3009 is proportional to the distance between the magnet 3931 and the sensing device 3009 if the strength of the magnet 3931 is fixed. In other words, by using the sensing device 3009 to detect whether the strength of the neighboring magnetic field exceeds a threshold value or not, the relative movement (or viewed as the relative motion) between the object 391 and the object 392 may be detected and announced by transmitting a wide-frequency sound signal or not.

In short, by using different kinds of the trigger module, many properties of the objected attached by the sensing device may be detected and presented as the variation of the transmitted wide-frequency sound signal. These embodiments presented above are just only examples of the invention but not the boundaries of the invention. For example, on some non-illustrated embodiments, the trigger module may use a gas flow meter to detect the flow rate of gas passing through the attached object and then sending a sensing signal only if the detected flow rate is larger than a threshold value. For example, on some non-illustrated embodiments, the trigger module may use a luxmeter to detect the light intensity on the attached object and then generating continuously a sensing signal whose value is proportion to the detected light intensity. And other electrochemical sensor is able to determine humidity, VOCs, and gas concentration are all used to related to the audio emitter module in this system.

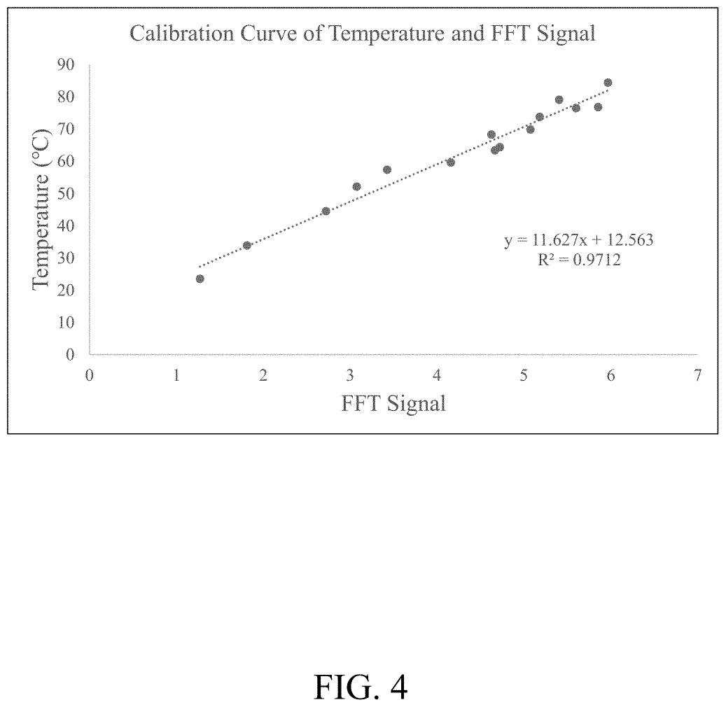

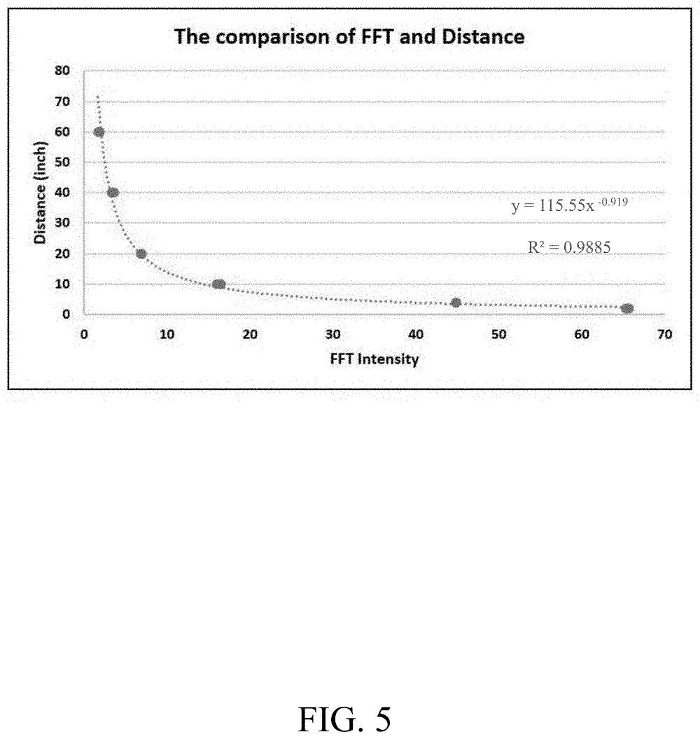

In addition, to emphasize the reliability of the invention, an experiment is processed to verify the difference between the real temperature and the detected temperature by using the sensing module containing the thermistor as shown in FIG. 3A as example. The experiment uses such sensing module to detect the temperature of an attached object fifteen times and then uses FFT (Fast Fourier Translation) to convert the detected result into a calibration curve of detected temperature and FFT signal strength. Then, five of the fifteen detected temperatures are selected to compare the corresponding practical temperature, the FFT signal and the FFT temperature acquired by using the linear equation fitted by these detected temperatures. TABLE 1 presents the values of the fifteen detected temperatures and their FFT signals, FIG. 4 shows these detected temperatures, these corresponding FFT signals and the linear equations fitted from them, and TABLE 2 presents these related values and the percentage gap therebetween. Significantly, the higher the detected temperature, the larger the FFT signal. Moreover, the relation between these detected temperatures and these FFT signals may be fitted properly as a straight line with the linear equation: y (Temperature)=11.627×(FFT Signal)+12.563, R²=0.9712. Further, during the detected range of this experiment, expect during the middle portion of the detected range, the percentage gap is mostly smaller than 10%, even approximately equal to or less than 7%. Therefore, without any doubt, by processing more experiments to further optimize at least the sensing module, such as to optimize the used special thermistor or even the used special crystal oscillator, the object temperature may be detected more accurately and converted more accurately into the wide-frequency sound signal. Emphasize that the invention is not limited by any special detail of the sensing module, such as any special combination of the thermistor and the crystal oscillator. Hence, more details are omitted to avoid any confusion.

TABLE 1

| No. | Temperature (° C.) | FFT Signal |
|---|---|---|
| 1 | 23.5 | 1.27187 |
| 2 | 33.9 | 1.812481 |
| 3 | 44.5 | 2.72028 |
| 4 | 52.1 | 3.076399 |
| 5 | 57.4 | 3.42678 |
| 6 | 59.6 | 4.160275 |
| 7 | 63.4 | 4.66622 |
| 8 | 64.4 | 4.722342 |
| 9 | 68.3 | 4.6258 |
| 10 | 69.9 | 5.075372 |
| 11 | 73.8 | 5.182765 |
| 12 | 76.5 | 5.601646 |
| 13 | 76.8 | 5.856073 |
| 14 | 79.1 | 5.406375 |
| 15 | 84.4 | 5.967403 |

TABLE 2

| | Real | | FFT | |
|---|---|---|---|---|
| | Temperature | | Temperature | Percentage Gap |
| | (° C.) | FFT Signal | (° C.) | (%) |
| T1 | 72.9 | 5.118606079 | 72.07703288 | 1.14% |
| T2 | 66.4 | 5.099171055 | 71.85106186 | 7.89% |
| T3 | 50 | 3.503179874 | 53.29447239 | 6.38% |
| T4 | 39.2 | 2.475096233 | 41.3409439 | 5.32% |
| T5 | 31.7 | 2.004443564 | 35.86866532 | 12.34% |

Furthermore, the proposed invention may be used to detect the position and/or the motion of one or more objects, even if the sensing devices attached on these objects do not detect directly the position and/or the motion of the attached object. That is to say, for each such sensing device, even if the wide-frequency sound signal just transmitted away is static and fixed, and/or even the sensing signal sent out by the sensing module is static and fixed). Note that the relative geometrical relation between a special object and an analyzing device is changed dynamically if the special object and/or the analyzing device is not statically fixed in the space. Thus, the wide-frequency sound signal just transmitted away the special object is different dynamically than the wide-frequency sound signal just received by the analyzing device, and then the dynamical difference is useful for detecting the relative distance and/or the relative motion velocity between the special object and the analyzing device.

As well-known, the amplitude of a signal inversely proportional to the square of the distance in the three-dimension space. Therefore, the analyzing device may decide the variation on the relative distance between itself and an object attached by a sensing device by analyzing the variation of the amplitude of the received wide-frequency sound signal transmitted from the sensing device. Moreover, the analyzing device decides the relative distance between the analyzing device and the certain sensing device (or viewed as the object attached by the certain sensing device) by comparing the internal amplitude of the wide-frequency sound signal and the practical amplitude of the wide-frequency sound signal when the signal is just received by the analyzing device. As usual, the analyzing device may preload the initial amplitude of the wide-frequency sound signal of a certain sensing device which the signal is just transmitted by the certain sensing device.

As well-known as Doppler effect, the relative motion between a transmitter and a receiver induces the frequency difference between the received wave and the transmitted wave. Therefore, the analyzing device may decide the variation on the relative motion between itself and an object attached by a sensing device by analyzing the variation of the frequency the received wide-frequency sound signal transmitted from the sensing device. Moreover, the analyzing device decides the relative motion between the analyzing device and the certain sensing device (or viewed as the object attached by the certain sensing device) by comparing the internal frequency of the wide-frequency sound signal and the practical frequency of the wide-frequency sound signal when the signal is just received by the analyzing device. As usual, the analyzing device may preload the initial frequency of the wide-frequency sound signal of a certain sensing device which the signal is just transmitted by the certain sensing device.

The proposed sensing device and the proposed determining system may be applied on many applications. For example, the intelligent fitness equipment many use the invention to monitor any movement of any portions of any fitness equipment. Herein, how to monitor may use any well-known skills used by the currently available intelligent fitness equipment, but the wide-frequency sound signal used by the invention may replace Wi-Fi, Bluetooth or other wireless communication used by the currently available intelligent fitness equipment. For example, the IOT may use the invention to provide communication among a lot of devices, because an analyzing device may receive signals from a number of sensing devices where the signals transmitted by these sensing devices vary only slightly in frequency from one another.

Additionally, to emphasize the reliability of the invention, an experiment is processed to verify the difference between the actual distance and the predict distance by using the determining system containing the sound module for emitting an ultrasound of 32 KHz frequency and the analyzing device containing a smartphone with a Hi-Res ADC microphone as example. The experiment uses such determining system to detect the different distances between an attached object and the analyzing device and then uses FFT (Fast Fourier Translation) to convert the detected result into a calibration curve of predict distance and FFT signal strength. TABLE 3 presents the values of the predict distances, their FFT signals, the actual distances, and the percentage gap between the predict distances and the actual distances. Significantly, the higher the predict distance, the smaller the FFT signal. Moreover, the relation between these predict distances and these FFT signals may be fitted properly as a curve with the equation of degree n (n≠1) with two variables: y (Distance)=115.55×(FFT Signal) ^{-0.919}, R²=0.9885. Besides, no matter how the actual distance and the FFT signal are, the percentage gap between the actual distance and the FFT Distance (Distance calculated by the equation of degree n (n≠1) with the FFT signal value) is constantly within the range of 0% to 3%. Therefore, without any doubt, by processing more experiments to further optimize at least the determining system, such as to optimize the used sound module, the used analyzing device or even the used special crystal oscillator, the object distance may be detected more accurately and converted more accurately into the wide-frequency sound signal. Emphasize that the invention is not limited by any special detail of the determining system, such as any special combination of the sound module, the analyzing device and the crystal oscillator. Hence, more details are omitted to avoid any confusion.

TABLE 3

| | Predict Distance | Actual Distance | Percentage |
|---|---|---|---|
| FFT Intensity | (inch) | (inch) | Gap (%) |
| 29.8762761 | 5.092662889 | 5 | 0% |
| 13.3687039 | 10.66335529 | 10 | 2% |
| 8.89198494 | 15.51101177 | 15 | 1% |
| 7.05560728 | 19.18522233 | 20 | 1% |
| 5.06011275 | 26.04034489 | 25 | 1% |
| 2.89526723 | 43.49888011 | 50 | 3% |
| 1.83940004 | 65.99826656 | 60 | 2% |
| 1.7147824 | 70.39338726 | 70 | 0% |

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A sensing device, comprising:
a trigger module, configured to generate a sensing signal corresponding to one or more properties of an object attached by the sensing device; and
a sound module, configured to generate and transmit a wide-frequency sound signal according to the sensing signal.

2. The device according to claim 1, further comprising a crystal oscillator module so that the trigger module, the crystal oscillator module and the sound module forms a circuit, wherein both the oscillation signal generated by the crystal oscillator module and the sensing signal are transmitted into the sound module and then used to generate the wide-frequency sound signal when the trigger module is triggered, and wherein both the oscillation signal generated by the crystal oscillator module and the sensing signal are not transmitted into the sound module and then no wide-frequency sound signal is generated correspondingly when the trigger module is not triggered.

3. The device according to claim 2, wherein each crystal oscillator generates an individual oscillation signal and the oscillation signal generated by the crystal oscillator module is dependent on which portion of the one or more crystal oscillators are connected electrically with the trigger module and the sound module.

4. The device according to claim 1, wherein the wide-frequency sound signal is chosen from a group consisting of the following: an audio signal and an ultrasonic signal.

5. The device according to claim 1, further comprising one of the following:
the frequency of the wide-frequency sound signal is fixed; and
the frequency of the wide-frequency sound signal is adjustable according to the operation of the trigger module.

6. The device according to claim 1, wherein the trigger module contains a thermistor so that the sensing signal is related to a temperature detected by the thermistor.

7. The device according to claim 1, wherein the trigger module contains a conductor ball located inside a pipe so that the sensing signal is related to an inclination detected by the conductor ball located inside the pipe.

8. The device according to claim 1, wherein the trigger module contains a mercury switch so that the sensing signal is related to an inclination detected by the mercury switch.

9. The device according to claim 1, wherein the trigger module contains a Hall effect switch so that the sensing signal is related to a magnetic field detected by the Hall effect switch.

10. The device according to claim 1, wherein the trigger module contains a spring switch so that the sensing signal is related a motion detected by the spring switch.

11. The device according to claim 1, wherein the trigger module contains a roll ball located inside a combination of a conductive tube and an insulated tube so that the sensing signal is decided by whether the roll ball enters the conductive tube or the insulated tube.

12. The device according to claim 1, wherein the trigger module contains a roll ball located inside a combination of one or more conductive tubes and one or more insulated tubes so that the sensing signal is decided by which conductive tube is entered by the roll ball.

13. The device according to claim 1, wherein the trigger module contains a spherical structure wherein some conductive lines and some holes are embedded with the inner of the spherical surface and wherein some conductive balls are located on the inner of the spherical structure, wherein each conductive line has one or more holes and each hole may be filled fully by at least one conductive ball so that the sensing signal is related to the multiple dimensions motion detection with speed and gravity effects.

14. The device according to claim 1, wherein the trigger module contains an electrochemical sensor, to determine gas concentration, humidity, VOCs, and change the voltage, resistant, or current to sensing signals in audio.

15. A determining system, comprising:
one or more sensing devices, wherein each sensing device is configured to transmit a wide-frequency sound signal corresponding to one or more properties of an object attached by the sensing device; and
an analyzing device, wherein the analyzing device is configured to receive and analyze one or wide-frequency sound signals transmitted from the one or more sensing devices.

16. The system according to claim 15, wherein different sensing devices transmits different wide-frequency sound signals having different frequencies.

17. The system according to claim 15, wherein each wide-frequency sound signal is chosen from a group consisting of the following: an audio signal and an ultrasonic signal.

18. The system according to claim 15, wherein each sensing device having a trigging module configured to generate a sensing signal corresponding to one or more properties of the object attached by the sensing device and a sound module to generate and transmit the wide-frequency sound signal according to the sensing signal.

19. The system according to claim 18, wherein at least one sensing device further has a crystal oscillator module having at least one crystal oscillator so that the trigger module, the crystal oscillator module and the sound module forms a circuit, wherein both the oscillation signal generated by the crystal oscillator module and the sensing signal are transmitted into the sound module and then used to generate the wide-frequency sound signal when the trigger module is triggered, and wherein both the oscillation signal generated by the crystal oscillator module and the sensing signal are not transmitted into the sound module and then no wide-frequency sound signal is generated correspondingly when the trigger module is not triggered.

20. The system according to claim 15, further comprising one or more of the following:
the analyzing device decides the variation on the relative distance between itself and an object attached by a sensing device by analyzing the variation of the amplitude of the received wide-frequency sound signal transmitted from the sensing device; and
the analyzing device decides the relative distance between the analyzing device and a sensing device by comparing the internal amplitude of the wide-frequency sound signal when the signal is just transmitted by the sensing device and the practical amplitude of the wide-frequency sound signal when the signal is just received by the analyzing device.

21. The system according to claim 15, further comprising one or more of the following:
the analyzing device decides the variation on the relative motion between itself and an object attached by a sensing device by analyzing the variation of the frequency of the received wide-frequency sound signal transmitted from the sensing device; and
the analyzing device decides the relative motion between the analyzing device and a sensing device by comparing the internal frequency of the wide-frequency sound signal when the signal is just transmitted by the sensing device and the practical frequency of the wide-frequency sound signal when the signal is just received by the analyzing device.
